(19) United States
(12) Patent Application Publication
(10) Pub. No.: US 2011/0180933 A1
(43) Pub. Date: Jul. 28, 2011

(54) SEMICONDUCTOR MODULE AND SEMICONDUCTOR MODULE MANUFACTURING METHOD

(76) Inventors: Yasunori Inoue, Gifu (JP); Hideki Mizuhara, Aichi (JP); Ryosuke Usui, Aichi (JP); Kenichi Ezaki, Osaka (JP); Hironori Nagasaki, Osaka (JP); Mayumi Nakasato, Gifu (JP)

(21) Appl. No.: 12/995,320

(22) PCT Filed: May 29, 2009
(86) PCT No.: PCT/JP2009/002400

§ 371 Date: Apr. 14, 2011

(30) Foreign Application Priority Data
May 30, 2008 (JP) 2008-143870

(51) Int. Cl. H01L 23/48; H01L 21/78

(52) U.S. Cl. 257/774; 438/113; 257/E23.011; 257/E21.599

(57) ABSTRACT

A wiring layer is formed on a substrate, and a semiconductor device is mounted on the substrate. The wiring layer and the semiconductor device are sealed by a sealing resin. A conductive member is used to fill a through hole formed in the sealing resin in a predetermined position of the wiring layer and is provided so as to cover over the sealing resin. The metal foil is provided on the upper surface of the conductive member, and the metal foil and the wiring layer are electrically connected via the conductive member.

### TECHNICAL FIELD

The present invention relates to a semiconductor module provided with an electromagnetic shield and to a method of manufacturing the semiconductor module.

### BACKGROUND

With the accelerating trend toward multi-functional portable electronic devices such as mobile phones, PDAs, DVCs, and DSCs, miniaturization and reduced weight have become essential features for these products to be competitive in the market. For this to be realized, there is a strong need for the development of highly-integrated system LSI. At the same time, more convenient, easy-to-use electronic devices are required, and there is a strong need for multi-functional and high-performance LSI to be applied to the devices. For this reason, while the number of I/Os (the number of input/output units) increases with the high integration of LSI chips, there is also a strong demand for miniaturization of packages. In order to achieve a balance between them, the development of semiconductor packages suitable for high-density board mounting of semiconductor components is in strong demand. To meet such a demand, a variety of packaging technique called CSP (Chip Size Package) has been developed.

In such a CSP-type semiconductor module, a technique of wrapping a semiconductor module to shield electromagnetic waves by a metal cap called can is known (see patent document 1).

[Patent document 1] Japanese Patent Application (Laid-Open) No. 2004-260103

### DISCLOSURE OF THE INVENTION

### Technical Problem

In a conventional can shield, it is necessary to provide a margin between a package and a can shield of a semiconductor module, and miniaturization of the entire semiconductor module including the can shield is therefore difficult.

Also, a technique of improving the reliability of connection between a conductive member and a wiring layer is necessary in the case of electrically connecting the can shield and the wiring layer provided on a substrate with use of the conductive member.

In this background, a purpose of the present invention is to reduce the size of a semiconductor module provided with an electromagnetic shield and to provide a technique of improving the reliability of electrical connection between the electromagnetic shield and a wiring layer provided on a substrate.

### Means for Solving the Problem

An embodiment of the present invention relates to a semiconductor module. The semiconductor module comprises: a substrate; a wiring layer formed on the substrate; a semiconductor device mounted on the substrate; a sealing resin which seals the semiconductor device and the wiring layer; a first conductive member formed in a through hole, which is formed, in the sealing resin, above a predetermined position of the wiring layer, or on the side surface of the sealing resin and provided so as to cover over the sealing resin; and a second conductive member provided between the first conductive member and the sealing resin or on the surface of the first conductive member on the opposite side from the sealing resin and having a smaller resistance than that of the first conductive member.

According to the embodiment, the second conductive member having a relatively small resistance functions as an electromagnetic shield, and the second conductive member and the sealing resin are in close contact with each other. Thus, the size of the semiconductor module can be reduced.

Another embodiment of the present invention relates to a manufacturing method of a semiconductor module. The manufacturing method of a semiconductor module comprises: preparing a substrate on which a wiring layer is formed; mounting a plurality of semiconductor devices on the substrate; connecting an external electrode provided on each of the plurality of semiconductor devices with the wiring layer; sealing the plurality of semiconductor devices all at once by using a sealing resin; forming a second conductive member so as to cover over the sealing resin; selectively removing the sealing resin and the second conductive member so that the substrate is exposed with respect to each semiconductor device; electrically connecting, by forming a first conductive member so as to cover the surface of the exposed substrate and cover over the second conductive member, the first conductive member and the second conductive member; and forming a semiconductor module by individuating an area including each semiconductor device.

Another embodiment of the present invention is a mobile device. The mobile device carries the semiconductor module described above.

### Advantageous Effects

The present invention allows for miniaturization of a semiconductor module provided with an electromagnetic shield and for provision of a technique of improving the reliability of electrical connection between the electromagnetic shield and a wiring layer provided on a substrate.

### BRIEF DESCRIPTION OF THE DRAWINGS

FIG. 1 is a sectional view showing the configuration of a semiconductor module according to a first embodiment;

FIGS. 2A to 2C are sectional views showing a method of manufacturing a semiconductor module according to the first embodiment;

FIGS. 3A to 3D are sectional views showing the method of manufacturing a semiconductor module according to the first embodiment;

FIG. 4 is a sectional view showing the configuration of a semiconductor module according to a second embodiment;

FIGS. 5A to 5D are sectional views showing a method of manufacturing a semiconductor module according to the second embodiment;

FIG. 6 is a sectional view showing the configuration of a semiconductor module according to a third embodiment;

FIGS. 7A to 7C are sectional views showing a method of manufacturing a semiconductor module according to the third embodiment;

FIGS. 8A to 8D are sectional views showing a method of manufacturing a semiconductor module according to the third embodiment;

FIG. 9 is a sectional view showing the configuration of a semiconductor module according to a fourth embodiment;

FIGS. 10A to 10B are sectional views showing a method of manufacturing a semiconductor module according to the fourth embodiment;

FIG. 11 is a sectional view showing the configuration of a semiconductor module according to a fifth embodiment;

FIGS. 12A to 12E are sectional views showing a method of manufacturing a semiconductor module according to the fifth embodiment;

FIG. 13 is a view showing the configuration of a mobile phone provided with the semiconductor module according to the fourth embodiment; and

FIG. 14 is a partial section of the mobile phone shown in FIG. 13 (sectional view of a first housing).

### EXPLANATION OF REFERENCE NUMERALS

10 semiconductor module

20 substrate

30 wiring layer

40 semiconductor device

50 sealing resin

60 conductive member

70 metal foil

72 conductive member

74 conductive member

### BEST MODE FOR CARRYING OUT THE INVENTION

Described below is an explanation of the embodiments of the present invention with reference to figures. In the figures, like numerals represent like constituting elements, and the description thereof is omitted appropriately.

### First Embodiment

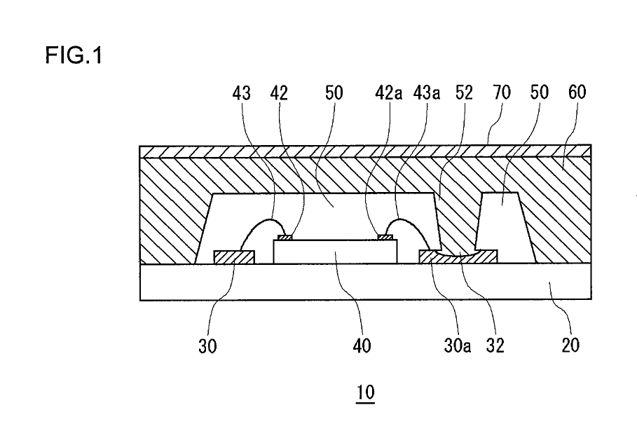

FIG. 1 is a sectional view showing the configuration of a semiconductor module according to a first embodiment. A semiconductor module 10 is provided with a substrate 20, a wiring layer 30, a semiconductor device 40, a sealing resin 50, a conductive member 60 as a “first conductive member,” and a metal foil 70 as a “second conductive member.”

The substrate 20 is made of a insulating resin such as an epoxy resin. The wiring layer 30 of a predetermined pattern is formed on the substrate 20 by using a metal such as a copper.

The semiconductor device 40 is an active device such as an IC (integrated circuit) or an LSI (large-scale integrated circuit). The semiconductor device 40 is mounted on the upper surface of the substrate 20 via an adhesive layer (not shown) such as a die attach film. An electrode pad 42 is provided on the periphery of the upper surface of the semiconductor device 40 as an external electrode, and the electrode pad 42 and the wiring layer 30 (more specifically, an electrode pad of a part of the wiring layer 30) are electrically connected by a wire 43 such as a gold wire. In FIG. 1, a ground potential is applied to an electrode pad 42a, a wire 43a, and a wiring layer 30a.

The semiconductor device 40 and the wiring layer 30 are sealed by the sealing resin 50. In the sealing resin 50, a through hole 52 is formed above a predetermined position of the wiring layer 30a to which the wire 43a is connected. One opening (bottom portion) of the through hole 52 faces the wiring layer 30a, and the other opening of the through hole 52 is formed on the upper surface of the sealing resin 50.

A concave area 32 whose diameter is larger than that of the bottom portion of the through hole 52 is provided on the wiring layer 30a at a predetermined position of the wiring layer 30a, in other words, a part that connects with the conductive member 60, which is described hereinafter. In other words, the concave area 32, reaching the bottom portion of the sealing resin 50, is formed around the opening of the through hole 52 on the side of the substrate 20. Thus, regarding the concave area 32, the wiring layer 30a in the lower portion of the sealing resin 50 is low around the opening of the through hole 52 on the side of the substrate 20.

The conductive member 60 is used to fill the concave area 32 provided in the through hole 52 and the wiring layer 30a provided in the sealing resin 50, and the cross-sectional shape of the through hole 52 is a so-called hammerhead shape. In the present embodiment, the conductive member 60 is provided on the upper surface and the side surface of the sealing resin 50. The upper surface of the conductive member 60 provided on the sealing resin 50 is flat and smooth. As the conductive member 60, a conductive paste such as a silver paste can be used.

The metal foil 70 is provided on the upper surface of the conductive member 60. The metal foil 70 is for example an aluminum foil. The metal foil 70 is electrically connected to the wiring layer 30a via the conductive member 60, and the electrical potential is fixed at the ground potential. Covering above the semiconductor device 40, the metal foil 70 functions as an electromagnetic shield, preventing outside electromagnetic noise from affecting the semiconductor device 40 and preventing electromagnetic noise produced by the semiconductor device 40 from leaking outside.

In the present embodiment, the conductive member 60 intermediates, as an adhesive layer, between the upper surface of the sealing resin 50 and the metal foil 70 and is also provided on the side surface of the sealing resin 50. However, the conductive member 60 does not need to be provided on the upper surface or the side surface of the sealing resin 50 as long as the wiring layer 30a and the metal foil 70 are in a conduction state via the conductive member 60.

According to the above-explained semiconductor module, the following advantage can be provided.

The thin metal foil 70 is used as an electromagnetic shield of the semiconductor module 10, and the conductive member 60 between the metal foil 70 and the sealing resin 50 is required to have at least a sufficient thickness for adhesion. Thus, it is not necessary to provide a margin between the metal foil 70 and the sealing resin 50, and the size of the semiconductor module 10 can be reduced.

In the opening of the through hole 52 on the side of the substrate 20, the conductive member 60 filling the through hole 52 is in contact with the wiring layer 30a, and the conductive member 60 is used to fill the through hole 52 while spreading to the bottom portion of the sealing resin 50 around the opening of the through hole 52 on the side of the substrate 20. This allows the conductive member 60, which fills the through hole 52 while spreading to the bottom portion of the sealing resin 50, to function as a “hooking portion” even when a force is applied to the conductive member 60 that pulls the conductive member 60 in the upward direction. Thus, the conductive member 60 is hard to be pulled out, and the reliability of connection between the conductive member 60 and the wiring layer 30a can be improved.

### The Manufacturing Method of a Semiconductor Module According to the First Embodiment

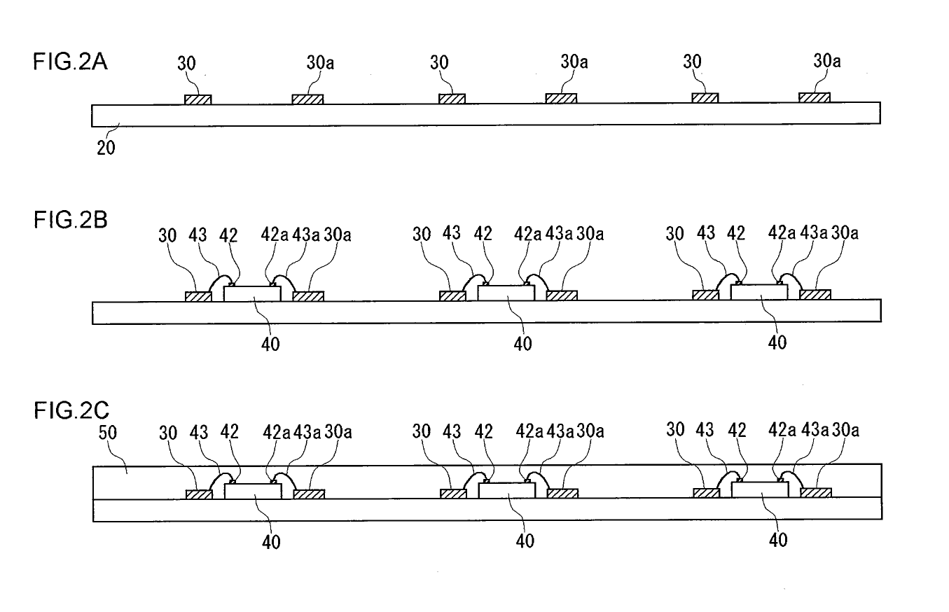

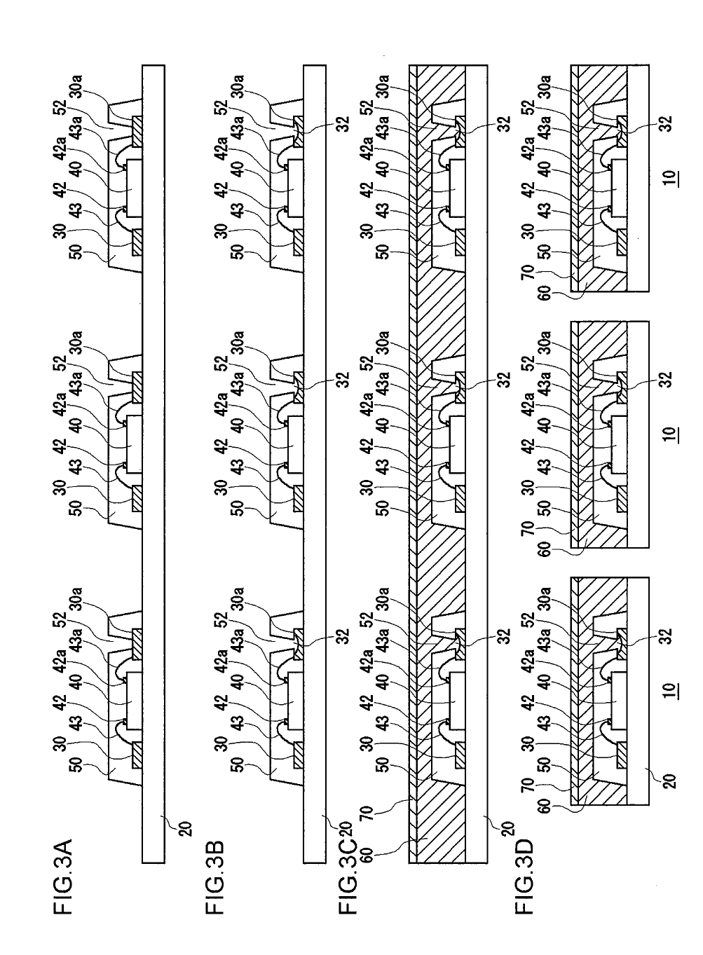

An explanation is given of the manufacturing method of a semiconductor module according to the first embodiment in reference to FIGS. 2-3.

As shown in FIG. 2A, the substrate 20 on which the wiring layer 30 is formed is prepared. The wiring layer 30 can be obtained by, for example, patterning a metal layer made of a copper by a photolithography process and an etching process.

As shown in FIG. 2B, the electrode pad 42, mounted on the upper surface of the semiconductor device 40, and the wiring layer 30 are electrically connected by a wire bonding method by using the wire 43 such as a gold wire after the semiconductor device 40 is mounted on the substrate 20 by using an adhesive layer such as a die attach film. The wiring layer 30a, among the wiring layers 30, is provided for connection with the wire 43a, and the wiring layer 30a may be an electrode pad.

As shown in FIG. 2C, a plurality of semiconductor devices 40 and wiring layers 30 on the substrate 20 are sealed all at once by the sealing resin 50, such as an epoxy resin, by dispensing.

As shown in FIG. 3A, a through hole 52 is formed in the sealing resin 50 by a laser process so as to expose a predetermined area of the wiring layer 30a. Also, the substrate 20 is exposed by a laser process at a predetermined area between adjacent semiconductor devices 40 so as to separate the sealing resin 50 into compartments for respective semiconductor devices 40. Regarding the order of performing the process of exposing the substrate 20 and the process of forming the through hole 52, either of the processes may be performed first. However, it is preferred to first perform the process of exposing the substrate 20 and then the process of forming the through hole 52 since a resin removed when exposing the substrate 20 will not attach inside the through hole 52 by first performing the process of exposing the substrate 20 and then performing the process of forming the through hole 52

As shown in FIG. 3B, a desmearing treatment with use of a chemical solution removes residues left at the exposed portion of the wiring layer 30a, and an acid-washing (washing by hydrochloric acid or the like) treatment then removes a thin oxidized film created on the surface of the wiring layer 30a by the chemical solution used for the desmearing treatment. This allows for the surface of the wiring layer 30a below the bottom opening of the through hole 52 to be etched concurrently, allowing for the concave area 32 having a diameter that is larger than that of the bottom portion of the through hole 52 to be formed. In the acid-washing treatment, the wiring layer 30a is selectively removed, and the concave area 32 is therefore formed, reaching the bottom portion of the sealing resin 50 around the opening of the through hole 52 on the side of the substrate 20.

As shown in FIG. 3C, the conductive member 60 made of a silver paste is applied so as to fill the area above the through hole 52 and the exposed portion of the substrate 20, and an unnecessary portion of the conductive member 60 is then removed, making the upper surface of the conductive member 60 to be flat and smooth, with use of a squeegee. Further, the metal foil 70 is placed on the upper surface of the conductive member 60 made to be flat and smooth. The metal foil 70 is, for example, an aluminum foil of a thickness of 50 μm. The metal foil 70 and the conductive member 60 being in contact with each other allow for the metal foil 70 and the wiring layer 30a to be electrically connected.

As shown in FIG. 3D, the substrate 20 is cut along a scribe line by a dicing process so as to individuate a plurality of semiconductor modules 10.

The semiconductor module according to the first embodiment can be manufactured by the above-explained manufacturing method. In the manufacturing method of a semiconductor module, the metal foil 70 that corresponds to the entire substrate 20 is placed on the conductive member 60, and the metal foil 70 is then separated concurrently when the semiconductor module 10 is individuated. Therefore, a process of providing an electromagnetic shield to each of the semiconductor modules 10 can be simplified and facilitated, allowing for laborsaving in manufacturing a semiconductor module.

### Second Embodiment

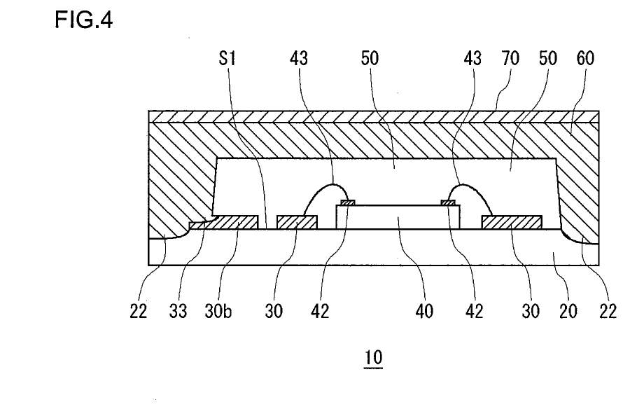

FIG. 4 is a sectional view showing the configuration of a semiconductor module according to a second embodiment. A description of structures similar to those of the first embodiment is appropriately omitted, and an explanation of the semiconductor module 10 according to the second embodiment is given mainly regarding structures that are different from those of the first embodiment in the following.

In the embodiment, a wiring layer 30b, which is a part of the wiring layer 30, protrudes outwardly from the side surface of the sealing resin 50. The electrical potential of the wiring layer 30b is fixed at the ground potential. A concave area 33, which is depressed below the surface of other wiring layers 30, is formed on the wiring layer 30b. The concave area 33 reaches the lower portion of the side surface of the sealing resin 50. A concave area 22, which is depressed below a main surface S1 of the substrate 20, is formed on the substrate 20 that is adjacent to the concave area 33 of the wiring layer 30b. A concave area 22, which is depressed below the main surface S1 of the substrate 20, is formed on the substrate 20 on the side of the sealing resin 50, on the side where the wiring layer 30b does not protrude outwardly.

The conductive member 60 is applied on the side surfaces and the upper surface of the sealing resin 50 and is electrically connected to the wiring layer 30b, which protrudes outwardly from one of the side surfaces of the sealing resin 50.

In the semiconductor module 10 according to the second embodiment, the closeness of contact between the conductive member 60 and the wiring layer 30b can be improved by filing the conductive member 60 in the concave area 33 of the wiring layer 30b based on a similar principle as that of the first embodiment. In addition to this effect, in the semiconductor module 10 according to the second embodiment, the interface (contact area) between the conductive member 60 and the substrate 20 is increased, and the closeness of contact between the conductive member 60 and the substrate 20 can be improved by filing the conductive member 60 in the concave area 22 provided on the substrate 20 that is adjacent to the concave area 33 of the wiring layer 30b.

### The Manufacturing Method of a Semiconductor Module According to the Second Embodiment

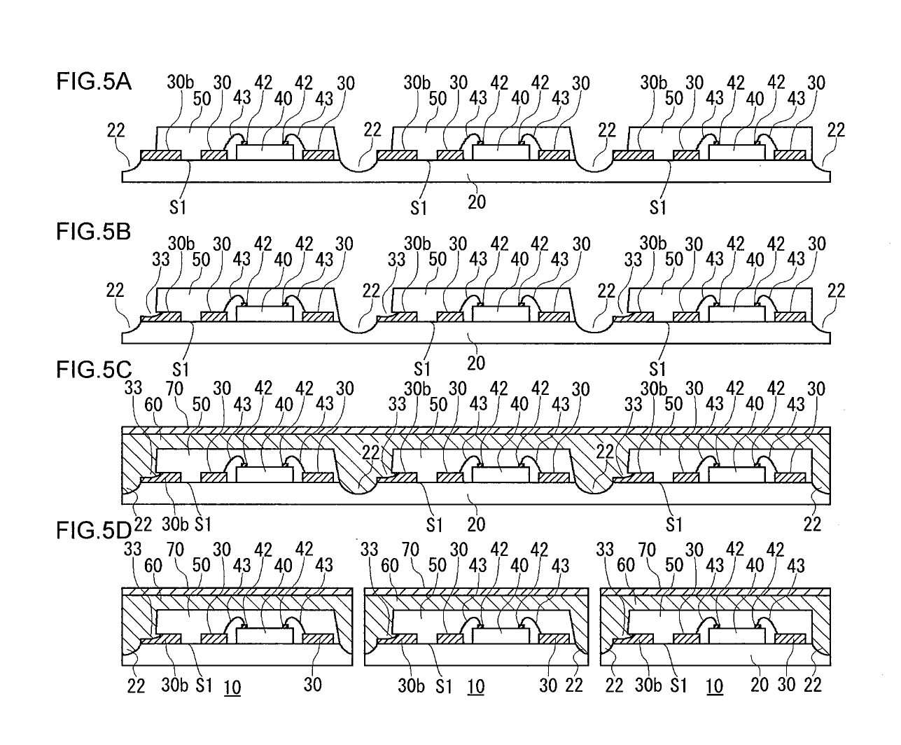

An explanation is given of the manufacturing method of a semiconductor module according to the second embodiment in reference to FIG. 5.

The manufacturing method of a semiconductor module according to the second embodiment includes the same processes as those shown in FIGS. 2A-2C in common with the manufacturing method of a semiconductor module according to the first embodiment. Note that although FIG. 2 is different from FIG. 5 in that the wiring layer 30b is not formed, it is assumed that the wiring layer 30b is formed at the position shown in FIG. 5 at the same time the wiring layer 30a is formed in FIGS. 2A-2C.

After the process shown in FIG. 2C, the substrate 20 is exposed by a laser process at a predetermined area between adjacent semiconductor devices 40 so as to separate the sealing resin 50 into compartments for respective semiconductor devices 40, as shown in FIG. 5A. The sealing resin 50 is removed such that the wiring layer 30b, whose electrical potential is fixed at the ground potential, is exposed on the side of the sealing resin 50. More specifically, the concave area 22, which is depressed below the main surface S1 of the substrate 20, is formed on the substrate 20 that is adjacent to the wiring layer 30b by adjusting the number of laser shots. In other words, one end of the concave area 22 reaches the side of the adjacent sealing resin 50 of the semiconductor device 40.

As shown in FIG. 5B, a desmearing treatment with use of a chemical solution removes residues left at the exposed portion of the wiring layer 30b, and the concave area 33 is formed on the wiring layer 30b by selectively removing the wiring layer 30b, the concave area 33 reaching the bottom portion of the side surface of the sealing resin 50.

As shown in FIG. 5C, the conductive member 60 made of a silver paste is applied on the side surface and the upper surface of the sealing resin 50, and an unnecessary portion of the conductive member 60 is then removed, making the upper surface of the conductive member 60 to be flat and smooth, with use of a squeegee. Further, the metal foil 70 is placed on the upper surface of the conductive member 60 made to be flat and smooth. The metal foil 70 is, for example, an aluminum foil of a thickness of 50 μm. The metal foil 70 and the conductive member 60 being in contact with each other allow for the metal foil 70 and the wiring layer 30b to be electrically connected.

As shown in FIG. 5D, the substrate 20 is cut along a scribe line by a dicing process so as to individuate a plurality of semiconductor modules 10.

The semiconductor module according to the second embodiment can be manufactured by the above-explained manufacturing method.

### Third Embodiment

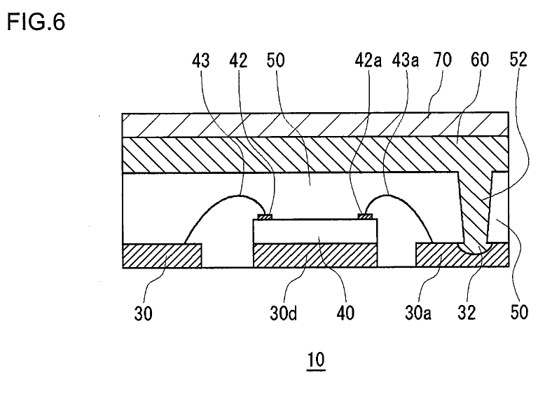

FIG. 6 is a sectional view showing the configuration of a semiconductor module according to a third embodiment. A description of structures similar to those of the first embodiment is appropriately omitted, and an explanation of the semiconductor module 10 according to the third embodiment is given mainly regarding structures that are different from those of the first embodiment in the following.

In the present embodiment, a substrate made of resin such as the one used in the first embodiment is not used. Therefore, the sealing resin 50 between the wiring layer 30 and the adjacent wiring layer 30 is exposed on the bottom surface of the semiconductor module 10.

More specifically, the wiring layer 30 of the present embodiment is a lead frame. A lead frame is a plate-like body obtained by molding a plate made of a metal such as a nickel alloy. An example of a lead frame is disclosed in, for example, Japanese Patent Application Publication No. 2001-127197.

The semiconductor device 40 of the present embodiment is mounted on a wiring layer 30d of a lead frame for mounting the semiconductor device 40.

The semiconductor module 10 according to the present embodiment allows for further reduction in size of a semiconductor module 10 since it is not necessary to use a substrate.

### The Manufacturing Method of a Semiconductor Module According to the Third Embodiment

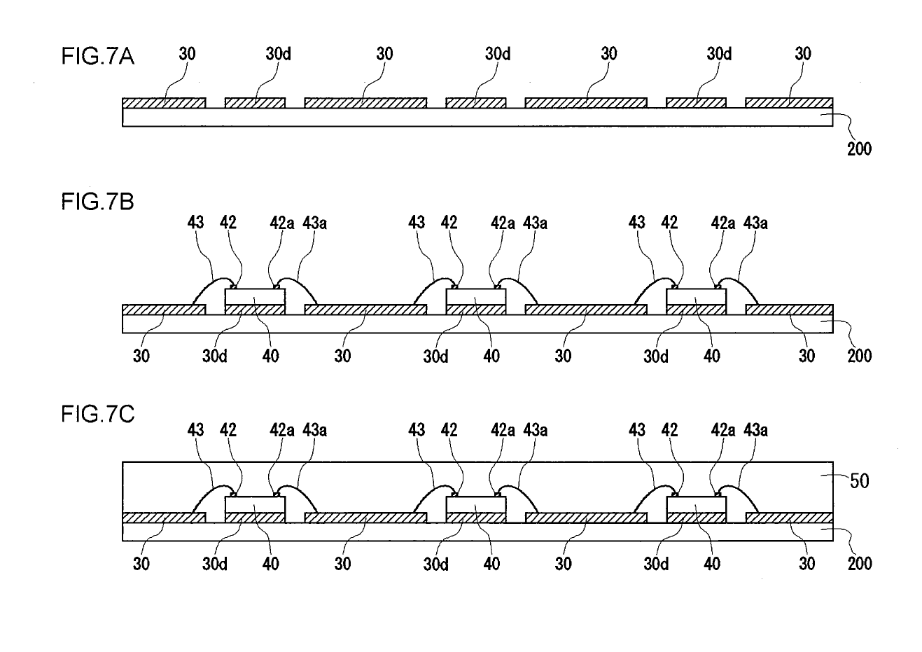

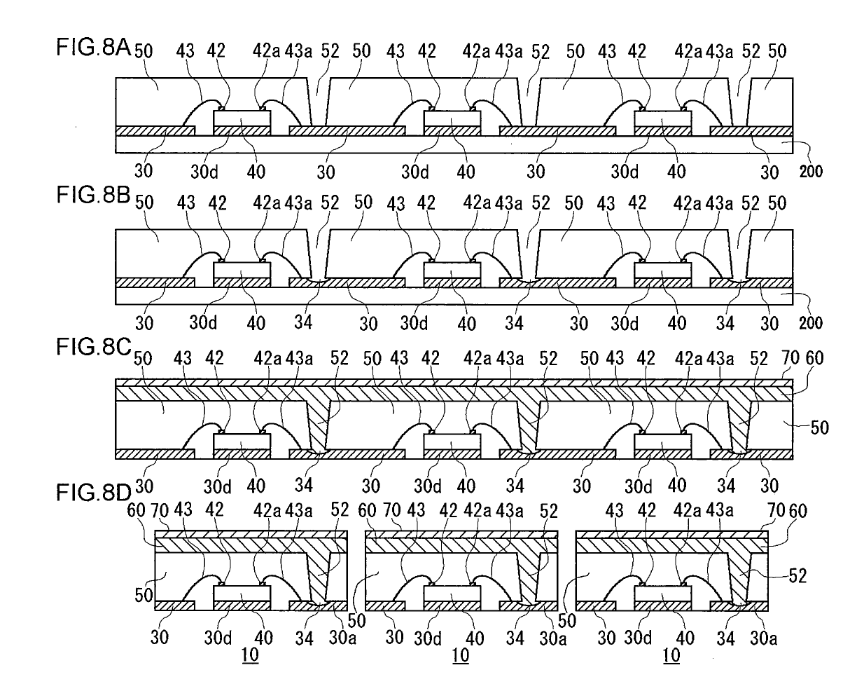

An explanation is given of the manufacturing method of a semiconductor module according to the third embodiment in reference to FIGS. 7-8.

As shown in FIG. 7A, a tape 200 is applied under the wiring layer 30. In the present embodiment, the wiring layer 30 is formed by a lead frame. The wiring layer 30d, among the wiring layers 30, is where the semiconductor device 40 is mounted.

As shown in FIG. 7B, the electrode pad 42, mounted on the upper surface of the semiconductor device 40, and the wiring layer 30 are electrically connected by a wire bonding method by using the wire 43 such as a gold wire after the semiconductor device 40 is mounted on a predetermined position of the wiring layer 30d by using a die attach film or the like.

As shown in FIG. 7C, a plurality of semiconductor devices 40 and wiring layers 30 on the tape 200 are sealed all at once by the sealing resin 50, such as an epoxy resin, by dispensing. The tape 200 applied below the wiring layer 30 prevents the sealing resin 50 from leaking out and allows for the sealing resin 50 to fill gaps between the wiring layers 30.

As shown in FIG. 8A, a through hole 52 is formed in the sealing resin 50 by a laser process so as to expose a predetermined area of the wiring layer 30.

As shown in FIG. 8B, a desmearing treatment with use of a chemical solution removes residues left at the exposed portion of the wiring layer 30, allowing for the concave area 34 having a diameter that is larger than that of the through hole 52 to be formed on the wiring layer 30 below the bottom opening of the through hole 52. In the desmearing treatment, the wiring layer 30 is selectively removed, and the concave area 34 is therefore formed, reaching the bottom portion of the sealing resin 50 around the opening of the through hole 52 on the side of the wiring layer 30.

As shown in FIG. 8C, the conductive member 60 made of a silver paste is applied so as to fill the through hole 52, and an unnecessary portion of the conductive member 60 is then removed, making the upper surface of the conductive member 60 to be flat and smooth, with use of a squeegee. Further, the metal foil 70 is placed on the upper surface of the conductive member 60 made to be flat and smooth. The metal foil 70 is, for example, an aluminum foil of a thickness of 50 μm. The metal foil 70 and the conductive member 60 being in contact with each other allow for the metal foil 70 and the wiring layer 30 to be electrically connected.

As shown in FIG. 8D, a lead frame 100 is cut by a dicing process, after peeling the tape 200 off, so as to individuate a plurality of semiconductor modules 10.

The semiconductor module according to the third embodiment can be manufactured by the above-explained manufacturing method.

### Fourth Embodiment

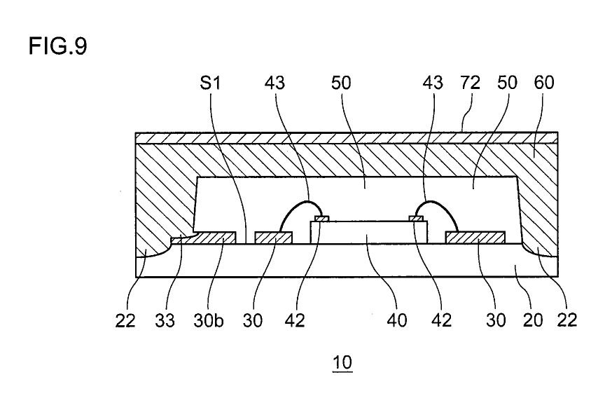

FIG. 9 is a sectional view showing the configuration of a semiconductor module according to a fourth embodiment. The semiconductor module according to the fourth embodiment shares common basic structures with the semiconductor module according to the second embodiment. A description of structures similar to those of the second embodiment is appropriately omitted, and an explanation of the semiconductor module 10 according to the fourth embodiment is given mainly regarding structures that are different from those of the second embodiment in the following.

The semiconductor module 10 according to the fourth embodiment is provided with a conductive member 72, which is different from the conductive member 60, instead of the metal foil 70 in the second embodiment as a “second conductive member.” In other words, the conductive member 72 is provided on the upper surface of the conductive member 60 in the same way as in the second embodiment. The conductive member 72 is electrically connected to the wiring layer 30b via the conductive member 60, and the electrical potential is fixed at the ground potential. Covering above the semiconductor device 40, the conductive member 72 functions as an electromagnetic shield, preventing outside electromagnetic noise from affecting the semiconductor device 40 and preventing electromagnetic noise produced by the semiconductor device 40 from leaking outside.

As the conductive member 72, a conductive paste such as a silver paste can be used. Note that the conductive member 72 is a member having properties different from those of the conductive member 60 in respect of the following points. The conductive member 72 has a lower resistance compared to that of the conductive member 60. The conductive member 72 has high viscosity compared to that of the conductive member 60 when being in a paste form. As described above, the conductive member 72, having a relatively low resistance, functions as an electromagnetic shield. In particular, since a high-frequency electromagnetic wave easily propagates over the surface of an object, providing the conductive member 72, having a relatively low resistance, on the outermost surface of the semiconductor module 10 can suppress the influence of noise from outside. A description will be given, in the manufacturing method of the semiconductor module according to the fourth embodiment, of the effect of having the viscosity of the conductive member 60 in the past form to be relatively low.

Forming both the conductive member 72 and the conductive member 60 by an conductive paste increases the closeness of contact between the conductive member 72 and the sealing resin 50 without creating any useless space in the direction of lamination, allowing for the reduction in the size of the semiconductor module 10.

### The Manufacturing Method of a Semiconductor Module According to the Fourth Embodiment

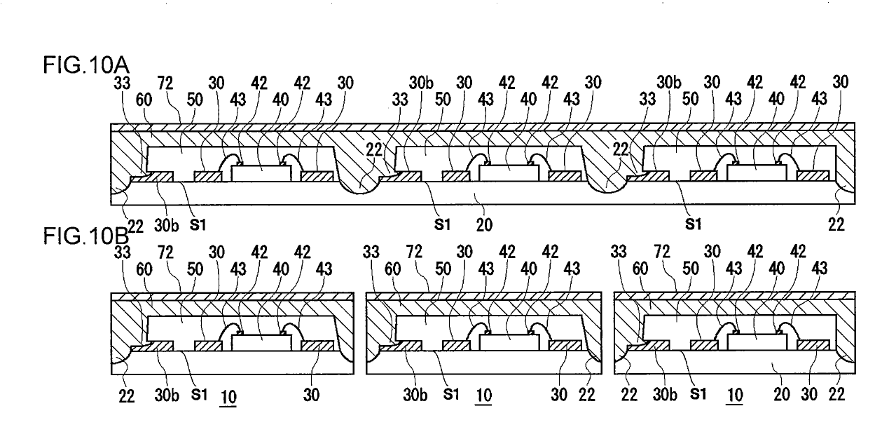

An explanation is given of the manufacturing method of a semiconductor module according to the fourth embodiment in reference to FIG. 10. The manufacturing method of a semiconductor module according to the fourth embodiment includes the same processes, as those are shown in up to FIG. 5B, in common with that of the semiconductor module according to the second embodiment.

Following the process shown in FIG. 5B, the conductive member 60 in a paste form is applied on the side surface and the upper surface of the sealing resin 50, and an unnecessary portion of the conductive member 60 is then removed, making the upper surface of the conductive member 60 to be flat and smooth, with use of a squeegee, as shown in FIG. 10A. Further, after the conductive member 60 is hardened, the conductive member 72 in a paste form is applied on the upper surface of the conductive member 60, and the conductive member 72 is then hardened. The conductive member 72 formed on the conductive member 60 while being in close contact with the conductive member 60 allows for the conductive member 72 and the wiring layer 30b to be electrically connected via the conductive member 60.

Compared to the conductive member 60, the conductive member 72 has a lower resistance and has higher viscosity in a paste form.

The conductive member 72 includes, for example, an insulating resin adhesive and a plurality of conductive particles. As an insulating resin adhesive for the conductive member 72, an insulating resin such as an epoxy resin or an acrylic resin can be used. As the plurality of conductive particles, metal particles having high electrical conductivity such as Cu or Ag can be used. The specific resistance of the conductive member 72 is, for example, about 4*10⁻⁵ Ωm. The viscosity of the conductive member 72 is, for example, 50-300 Pa·s.

The conductive member 60 includes, for example, an insulating resin adhesive and a plurality of conductive particles. As an insulating resin adhesive for the conductive member 60, an insulating resin such as a phenol resin, an epoxy resin, or an acrylic resin can be used. As the plurality of conductive particles, metal particles having high electrical conductivity such as Cu or Ag can be used. The specific resistance of the conductive member 60 is, for example, about 5*10⁻⁵ Ωm. The viscosity of the conductive member 60 is, for example, 3-10 Pa·s.

As described above, the conductive member 60 has a relatively low viscosity in a paste form, in other words, has high fluidity. Therefore, the conductive member 60 can easily flow into the concave area 33, which is provided on the wiring layer 30b, and into the concave area 22, which is provided on the sealing resin 50, preventing the generation of a void in the concave area 33 or in the concave area 32. Furthermore, the reliability of connection between the conductive member 60 and the wiring layer 30b can be improved. The difference between the specific resistance of the conductive member 60 and the specific resistance of the conductive member 72 can be achieved by adjusting the content of the conductive particles. The difference between the viscosity of the conductive member 60 and the viscosity of the conductive member 72 in a paste form can be achieved by changing the viscosity of the resin adhesive or by changing the amount of adding a solvent if the resin adhesive has a similar viscosity.

As shown in FIG. 10B, the substrate 20 is cut along a scribe line by a dicing process so as to individuate a plurality of semiconductor modules 10.

The semiconductor module according to the fourth embodiment can be manufactured by the above-explained manufacturing method. In the manufacturing method of a semiconductor module, the conductive member 72 that covers the entire substrate 20 is formed, and the conductive member 72 is then separated concurrently when the semiconductor module 10 is individuated. Therefore, a process of providing an electromagnetic shield to each of the semiconductor modules 10 can be simplified and facilitated, allowing for laborsaving in manufacturing a semiconductor module.

### Fifth Embodiment

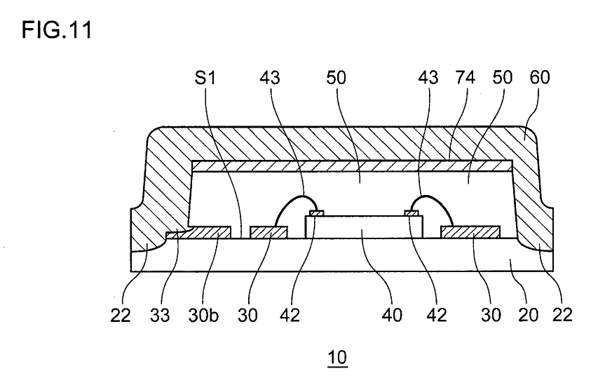

FIG. 11 is a sectional view showing the configuration of a semiconductor module according to a fifth embodiment. The semiconductor module according to the fifth embodiment shares common basic structures with the semiconductor module according to the second embodiment. A description of structures similar to those of the second embodiment is appropriately omitted, and an explanation of the semiconductor module 10 according to the fifth embodiment is given mainly regarding structures that are different from those of the second embodiment in the following.

The semiconductor module 10 according to the fifth embodiment is provided with a conductive member 74, which is different from the conductive member 60, instead of the metal foil 70 in the second embodiment as a “second conductive member.” Note that, in the present embodiment, the conductive member 74 is located between the upper surface of the sealing resin 50 and the conductive member 60. In other words, the conductive member 74 is provided on the upper surface of the sealing resin 50, and the conductive member 60 is provided on the upper surface and the side surface of the conductive member 74.

The conductive member 74 is electrically connected to the wiring layer 30b via the conductive member 60, and the electrical potential is fixed at the ground potential. Covering above the semiconductor device 40, the conductive member 74 functions as an electromagnetic shield, preventing outside electromagnetic noise from affecting the semiconductor device 40 and preventing electromagnetic noise produced by the semiconductor device 40 from leaking outside.

As the conductive member 74, a conductive paste such as a silver paste can be used. Note that the conductive member 74 is a member having properties different from those of the conductive member 60 in respect of the following points. The conductive member 74 has a lower resistance compared to that of the conductive member 60. The conductive member 74 has high viscosity compared to that of the conductive member 60 when being in a paste form. As described above, the conductive member 74, having a relatively low resistance, functions as an electromagnetic shield. A description will be given, in the manufacturing method of the semiconductor module according to the fifth embodiment, of the effect of having the viscosity of the conductive member 60 in the past form to be relatively low.

Forming both the conductive member 74 and the conductive member 60 by an conductive paste increases the closeness of contact between the conductive member 74 and the conductive member 60 and between the conductive member 74 and the sealing resin 50 without creating any useless space in the direction of lamination, allowing for the reduction in the size of the semiconductor module 10.

### The Manufacturing Method of a Semiconductor Module According to the Fifth Embodiment

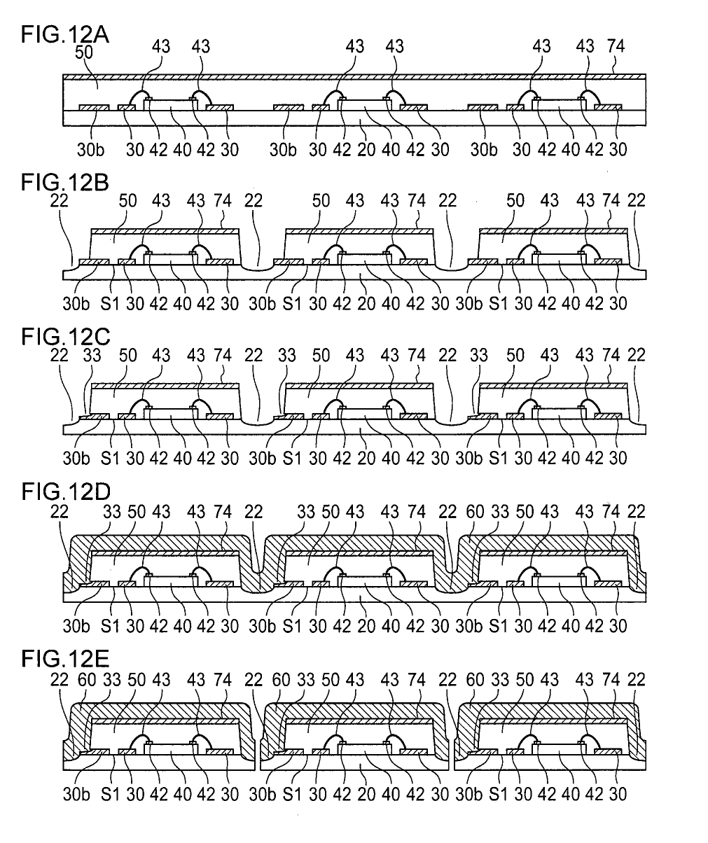

An explanation is given of the manufacturing method of a semiconductor module according to the fifth embodiment in reference to FIG. 12. The manufacturing method of a semiconductor module according to the fifth embodiment includes the same processes as those shown in up to FIG. 2C, which are the common processes shared with that according to the first embodiment, in common with that of the semiconductor module according to the second embodiment. Note that although FIG. 2 is different from. FIG. 12 in that the wiring layer 30b is not formed, it is assumed that the wiring layer 30b is formed at the position shown in FIG. 12 at the same time the wiring layer 30a is formed in FIGS. 2A-2C.

Following the process shown in FIG. 2C, the conduction member 74 in a paste form is applied on the upper surface of the sealing resin 50, and an unnecessary portion of the conductive member 74 is then removed, making the upper surface of the conductive member 74 to be flat and smooth, with use of a squeegee, as shown in FIG. 12A. The conductive member 74 includes, for example, an insulating resin adhesive and a plurality of conductive particles. As an insulating resin adhesive for the conductive member 74, an insulating resin such as an epoxy resin or an acrylic resin can be used. As the plurality of conductive particles, metal particles having high electrical conductivity such as Cu or Ag can be used. The specific resistance of the conductive member 74 is, for example, about 4*10⁻⁵ Ωm. The viscosity of the conductive member 74 is, for example, 50-300 Pa·s.

As shown in FIG. 12A, the substrate 20 is exposed by a laser process at a predetermined area between adjacent semiconductor devices 40 so as to separate the sealing resin 50 into compartments for respective semiconductor devices 40. At this time, the sealing resin 50 and the conductive member 74 are removed such that the wiring layer 30b, whose electrical potential is fixed at the ground potential, is exposed on the side of the sealing resin 50. More specifically, the concave area 22, which is depressed below the main surface S1 of the substrate 20, is formed on the substrate 20 that is adjacent to the wiring layer 30b by adjusting the number of laser shots. In other words, one end of the concave area 22 reaches the side of the adjacent sealing resin 50 of the semiconductor device 40.

As shown in FIG. 12C, a desmearing treatment with use of a chemical solution removes residues left at the exposed portion of the wiring layer 30b, and a concave area 33 is formed on the wiring layer 30b by selectively removing the wiring layer 30b, the concave area reaching the bottom portion of the side surface of the sealing resin 50.

As shown in FIG. 12D, the conductive member 60 in a paste form in applied over the entire surface from above the substrate 20. This allows for the conductive member 60 to be formed on the upper surface of the conductive member 74 while being in close contact with the conductive member 74 and allows for the side surface of the sealing resin 50, the concave area 22, and the concave area 33, which are located between the sealing resin 50 and the adjacent sealing resin 50 thereof, to be coated by the conductive member 60. This allows for the conductive member 74 and the wiring layer 30b to be electrically connected via the conductive member 60.

The conductive member 60 has a high resistance and has low viscosity in a paste form compared to those of the conductive member 74. The conductive member 60 includes, for example, an insulating resin adhesive and a plurality of conductive particles. As an insulating resin adhesive for the conductive member 60, an insulating resin such as a phenol resin, an epoxy resin, or an acrylic resin can be used.

As the plurality of conductive particles, metal particles having high electrical conductivity such as Cu or Ag can be used. The specific resistance of the conductive member 74 is, for example, about 5*10⁻⁵ Ωm. The viscosity of the conductive member 60 is, for example, 3-10 Pa·s. The conductive member 60 has a relatively low viscosity in a paste form, in other words, has high fluidity. Therefore, the conductive member 60 can easily get into the concave area 33 provided on the wiring layer 30b and into the concave area 22 provided on the sealing resin 50, preventing the generation of a void in the concave area 33 or in the concave area 32. Furthermore, the reliability of connection between the conductive member 60 and the wiring layer 30b can be improved. The difference between the specific resistance of the conductive member 60 and the specific resistance of the conductive member 74 can be achieved by adjusting the content of the conductive particles. The difference between the viscosity of the conductive member 60 and the viscosity of the conductive member 74 in a paste form can be achieved by changing the viscosity of the resin adhesive or by changing the amount of adding a solvent if the resin adhesive has a similar viscosity.

The conductive member 60 has high fluidity and is thus formed, with a certain film thickness, to follow the shapes of the upper surface of the conductive member 74, the side surface of the sealing resin 50, and the surfaces of the concave area 22 and concave area 33. Therefore, compared to when the conductive member 60 completely fills between the adjacent sealing resins 50, the amount of the conductive member 60 used can be reduced, further allowing for the reduction in manufacturing cost of a semiconductor module.

The semiconductor module according to the fifth embodiment can be manufactured by the above-explained manufacturing method. In the manufacturing method of a semiconductor module, the sealing resin 50 and the conductive member 74 that cover the entire substrate 20 are formed, and the conductive member 74 is then separated concurrently with the separation of the sealing resin 50. Therefore, a process of providing an electromagnetic shield to each of the semiconductor modules 10 can be simplified and facilitated, allowing for laborsaving in manufacturing a semiconductor module.

These embodiments are intended to be illustrative only, and it will be obvious to those skilled in the art that various modifications could be developed based on the knowledge of a skilled person and that such modifications are also within the scope of the semiconductor module of the present invention.

For example, in the above-stated first and second embodiments and fourth and fifth embodiments, a wiring layer may be provided on the side of the lower surface of the substrate 20, and the wiring layer may be connected to the wiring layer 30 on the side of the upper surface of the substrate 20 through a via provided on the substrate 20. A solder ball may be mounted on the wiring layer provided on the side of the lower surface of the substrate 20.

In the above-stated first through third embodiments, the metal foil 70 is placed after the conductive member 60 is applied and formed on the sealing resin 50. Another member having the conductive member 60 applied and formed on the metal foil 70 may be prepared, and the member may be placed on the sealing resin 50 with the conductive member 60 facing the sealing resin 50.

In the above-stated first through fifth embodiments, the semiconductor device 40 is connected by a wire bonding method; however, the semiconductor device 40 may be connected by a flip-chip method.

In the above-stated second, fourth, and fifth embodiments, the wiring layer 30b, a part of which protruding on the side of the sealing resin 50, and the conductive member 60 are in contact with each other; however, the conductive member 60 may come into contact with the wiring layer 30a provided in accordance with the through hole 52 by using the conductive member 60 so as to fill the through hole 52 provided in the sealing resin 50, as in the first embodiment.

A description will now be given of a mobile device provided with the semiconductor module according to the present invention. While a mobile phone is described to exemplify mobile devices, the inventive module may also be applied to electronic devices such as personal digital assistants (PDA), digital video cameras (DVC), a music player, and digital still cameras (DSC).

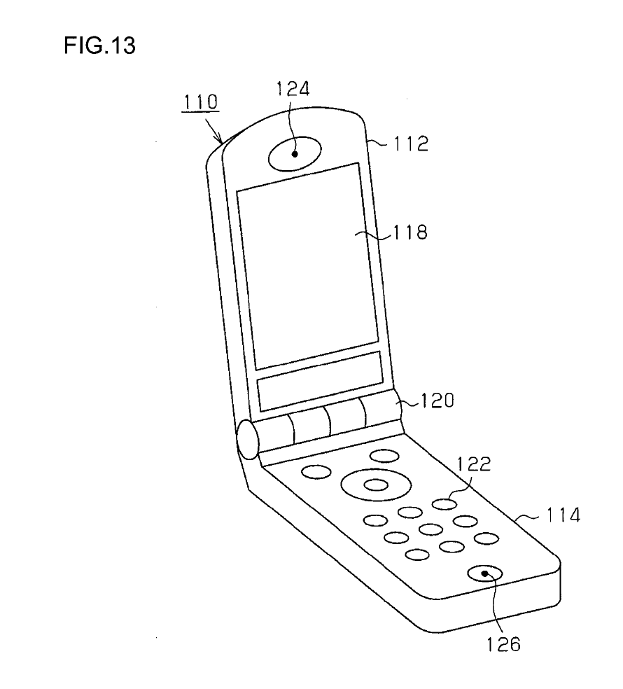

FIG. 13 shows the structure of a mobile phone according to the embodiment of the present invention provided with the semiconductor module. A mobile phone 110 is structured such that a first housing 112 and a second housing 114 are connected via a movable part 120. The first housing 112 and the second housing 114 are movable around the movable part 120. The first housing 112 is provided with a display unit 118 for displaying information including characters and images, and with a speaker unit 124. The second housing 114 is provided with a control 122 (e.g. control buttons) and a microphone unit 126. The semiconductor module according to the embodiments is mounted inside the mobile phone 110. As described above, the semiconductor module of the present invention, which is mounted on a mobile phone, can be employed as a power supply circuit for driving circuits, an RF generating circuit for generating an RF, a DAC, an encoder circuit, and a drive circuit of a backlight acting as a light source of a liquid crystal panel employed as a display of a mobile phone.

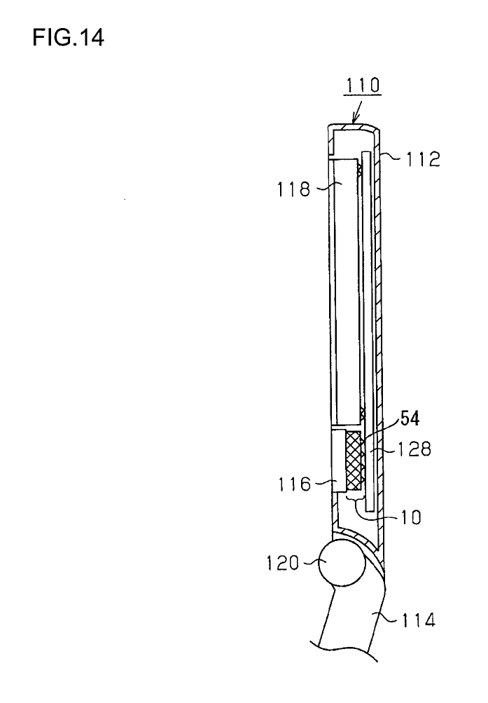

FIG. 14 is a partial section of the mobile phone shown in FIG. 13 (section of the first housing 112). The semiconductor module 10 according to the embodiments of the present invention is mounted on a printed board 128 via an electrode (solder ball) 54 for external connection, and electrically connected to, for example, the display unit 118 via the printed board 128. The underside of the semiconductor module 10 (the surface opposite to the electrode 54) is provided with a heat spreader 116 such as a metal plate. For example, heat generated by the semiconductor module 10 is prevented from collected inside the first housing 112 and is released outside the first housing 112 efficiently.

According to the mobile device provided with the semiconductor module according to the embodiments of the present invention, the following advantages are provided.

In the semiconductor module 10, since the connection reliability of a conductive member, which electrically connects a metal foil acting as an electromagnetic shield with a wiring layer, and a wiring layer is improved, the reliability of the mobile device carrying the semiconductor module 10 is improved.

Since heat from the semiconductor module 10 can be efficiently dissipated to the outside via the heat spreader 116, an increase in the temperature of the semiconductor module 10 can be prevented, reducing the thermal stress between the conductive member and the wiring layer. Therefore, compared to when the heat spreader 116 is not provided, the reliability (thermal reliability) of the semiconductor module 10 is improved since the conductive member inside the semiconductor module is prevented from coming off from the wiring layer. As a result, the reliability (thermal reliability) of the mobile phone can be improved.

Since the size of the semiconductor module 10 shown in the embodiments can be reduced, a mobile device carrying the semiconductor module 10 can be made to be slim and small.

### INDUSTRIAL APPLICABILITY

The present invention contributes to the thickness reduction and size reduction of a semiconductor module, provided with an electromagnetic shield, and a mobile device.

1-9. (canceled)

1. A semiconductor module comprising:
a substrate;
a wiring layer formed on the substrate;
a semiconductor device mounted on the substrate;
a sealing resin which seals the semiconductor device and the wiring layer;
a first conductive member formed in a through hole, which is formed, in the sealing resin, above a predetermined position of the wiring layer, or on the side surface of the sealing resin and provided so as to cover over the sealing resin; and
a second conductive member provided between the first conductive member and the sealing resin or on the surface of the first conductive member on the opposite side from the sealing resin and having a smaller resistance than that of the first conductive member.

2. The semiconductor module according to claim 1, wherein,
when the first conductive member is formed on the side surface of the sealing resin,
a concave area is formed on the substrate on the side of the sealing resin, and
the first conductive member is used to fill the concave area provided on the substrate.

3. A semiconductor module comprising:
a wiring layer;
a semiconductor device mounted in a device-mounting area of the wiring layer;
a sealing resin which seals the semiconductor device and the wiring layer;
a first conductive member formed in a through hole, which is formed, in the sealing resin, above a predetermined position of the wiring layer, or on the side surface of the sealing resin and provided so as to cover over the sealing resin; and
a second conductive member provided between the first conductive member and the sealing resin or on the surface of the first conductive member on the opposite side from the sealing resin and having a smaller resistance than that of the first conductive member.

4. The semiconductor module according to claim 1, wherein,
when the first conductive member is formed in the through hole,
a concave area, whose diameter is larger than the diameter of the bottom part of the through hole, is formed on the wiring layer in a position where the wiring layer and the first conductive member are in contact with each other.

5. The semiconductor module according to claim 3, wherein
when the first conductive member is formed in the through hole,
a concave area, whose diameter is larger than the diameter of the bottom part of the through hole, is formed on the wiring layer in a position where the wiring layer and the first conductive member are in contact with each other.

6. The semiconductor module according to claim 1, wherein the second conductive member is a metal foil.

7. The semiconductor module according to claim 3, wherein the second conductive member is a metal foil.

8. A manufacturing method of a semiconductor module comprising:
preparing a substrate on which a wiring layer is formed;
mounting a plurality of semiconductor devices on the substrate;
connecting an external electrode provided on each of the plurality of semiconductor devices with the wiring layer;
sealing the plurality of semiconductor devices all at once by using a sealing resin;
forming a second conductive member so as to cover over the sealing resin;
selectively removing the sealing resin and the second conductive member so that the substrate is exposed with respect to each semiconductor device;
electrically connecting, by forming a first conductive member so as to cover the surface of the exposed substrate and cover over the second conductive member, the first conductive member and the second conductive member; and
forming a semiconductor module by individuating an area including each semiconductor device.

9. The manufacturing method of a semiconductor module according to claim 6, wherein
a concave area is formed on the substrate when selectively removing the sealing resin and a second conductive member, and
a first conductive member is used to fill the concave area formed on the substrate when forming the first conductive member.

10. The manufacturing method of a semiconductor module according to claim 6, wherein
forming the first conductive member is a step of applying the first conductive member in a paste form, comprising:
selectively removing the sealing resin and the second conductive member, concurrently forming a concave area on the substrate; and
using the first conductive member to fill the concave area formed on the substrate.
